(19) United States
(12) Patent Application Publication
(10) Pub. No.: US 2003/0030998 A1
(43) Pub. Date: Feb. 13, 2003

(54) Microelectromechanical component

(75) Inventors: Ahmed Mhani, Grenoble (FR); Jean-Marc Fedeli, Saint Egreve (FR)

Correspondence Address: HESLIN ROTHENBERG FARLEY & MESITI PC, 5 COLUMBIA CIRCLE, ALBANY, NY, 12203, US

(73) Assignee: MEMSCAP, Saint Ismier (FR)

(21) Appl. No.: 10/186,332

(22) Filed: Jun. 28, 2002

(30) Foreign Application Priority Data
Jul. 2, 2001 (FR) 01 08743

(51) Int. Cl. H05K 7/02; H05K 7/06; H05K 7/08; H05K 7/10

(52) U.S. Cl. 361/760

(57) ABSTRACT

Microelectromechanical component (1) providing filtering functions, produced on a semiconductor-based substrate, and comprising two input terminals and two output terminals, characterized in that it also comprises:

a moveable element (4) connected to the substrate by at least one deformable portion, and including a region made of a ferromagnetic material;

a metal coil (5) connected to the input terminals or output terminals (30, 31), capable of interacting magnetically with the ferromagnetic region of the moveable element (4);

a surface forming a first electrode (6), connected to one of the output terminals or input terminals, placed opposite a complementary surface secured to the moveable element (4), this complementary surface forming a second electrode connected to the other of the output or input terminals, and being capable of interacting electrostatically with the first electrode (6).

### TECHNICAL FIELD

The invention relates to the field of microelectronics, and more exactly to that of components used in the radiofrequency ranges. More specifically, it provides a new structure for passive filters used in electronic circuits, and made from microelectromechanical systems known by the name “MEMS”.

### PRIOR ART

In the telecommunications field, various types of filter are used to carry out filtering functions, especially in the stages operating at intermediate frequency, or in oscillators, or else in other types of function.

Of the various filters used, mention may especially be made of quartz filters, and surface acoustic wave filters, also known by the abbreviation “SAW”. This type of filter operates by using piezoelectric phenomena. They are valued for their high quality factor and excellent stability, especially of the resonant frequency, with regard to temperature and ageing. However, because of technological limitations, the number of poles of such a filter cannot be very significantly increased. These same technological constraints make this type of filter very difficult to miniaturize much.

It has also been proposed to produce filters using MEMS technologies which operate on the basis of electrostatic phenomena.

Thus, in general, such a filter uses two plates operating as a capacitor.

The application of an AC voltage which depends on the input signal at the terminals of this capacitor causes a movement of the plate which is moveable, and therefore a variation of the capacitance of the capacitor, and consequently the variation of an output signal. The two plates are moveable one with respect to the other, and part of the system acts as a return member in order to oppose the deformation generated by the variation of the input signal. The natural frequency of this filter depends on the geometry of the structure, and on the bias voltage applied between the plates.

Several geometries have already been envisaged for filters operating solely on the basis of electrostatic phenomena.

Thus there are filters, or more generally resonators, in which the moveable plate moves perpendicular to the main plane of the substrate on which the microcomponent is produced. Some of these resonators may also be coupled to each other to improve performance. One of the drawbacks of this type of resonator is some sensitivity to pressure variations, which require encapsulation of the microcomponents under a vacuum or under very low pressure.

Moreover, other filters are known which operate on the basis of electrostatic phenomena and in which the moveable plate moves in a plane parallel to the main plane of the substrate on which the microcomponent is produced. The same goes for filters whose plates are formed by interdigitated combs. By virtue of this configuration, the surface areas opposite the other plates are relatively large, which makes it possible to obtain enough travel with bias voltages which are lower than for the solutions described above.

However, these solutions have certain limitations. This is because the natural frequency of such a resonator depends on the stiffness constant of the return means inserted between the plates, and on the mass of the moveable plate. Thus, in order to reach high resonant frequencies, it would be preferable to increase the stiffness constant while decreasing the mass of the moveable plate. However, the use of a high stiffness constant results in a low amplitude of movement of the moveable plate, which is not always enough to distinguish the generated signal correctly from the noise. A compromise therefore remains to be made between increasing the frequency of the filter and the amplitude of the output signal.

A first problem which the invention therefore proposes to solve is that of increasing the resonant frequencies of filters produced using MEMS technologies. Another problem which the invention proposes to solve is that of the need to produce vacuum packagings in order to preserve good filter stability and a high resonant frequency.

Another problem is that of the compatibility between increasing the resonant frequency and the output signal level, observed on the filters made in MEMS technology, operating on the basis of electrostatic phenomena. Another problem that the invention seeks to solve is that of using high bias voltages which generate relatively high consumption, to the detriment of autonomy, and which induce insulation stresses.

### SUMMARY OF THE INVENTION

The invention therefore relates to an electromechanical microcomponent providing filtering functions, produced on a semiconductor-based substrate, and comprising two input terminals and two output terminals.

According to the invention, this microcomponent also comprises:

a moveable element connected to the substrate by at least one deformable portion, and including a region made of a ferromagnetic material;

a metal coil connected to the input terminals or output terminals, capable of interacting magnetically with the ferromagnetic region of the moveable element;

a surface forming a first electrode, connected to one of the output terminals or input terminals, placed opposite a complementary surface secured to the moveable element, this complementary surface forming a second electrode connected to the other of the output or input terminals, and being capable of interacting electrostatically with the first electrode.

In other words, the filter operates by combining two energy conversions of different types. The moveable element can be made to move under the effect of a magnetic field, such that electrical energy is transformed into magnetic energy. This magnetic energy is physically embodied in the moveable element as kinetic energy which can in turn be transformed into electrical energy by phenomena of the electrostatic type. The reverse combination of the two energy conversions may also take place, that is to say that the moveable element can be made to move under the effect of electrostatic phenomena, this kinetic energy then being converted into electrical energy via an interaction of the magnetic type.

By converting electrical energy into magnetic energy and vice versa, the sensitivity of the filter to higher frequencies is improved in comparison with filters operating only on electrostatic principles. This is because the resonant frequency is increased by choosing a high ratio of the stiffness of the return means to the mass of the moveable element. Although the amplitudes of the mechanical oscillations are relatively small, a signal generated at the output stage which is large enough to be useable is however obtained.

More specifically, in a first scenario, the metal coil is connected to the input terminals and is capable of generating a magnetic field when a current flows through it. The moveable element itself is capable of moving under the effect of the force to which the ferromagnetic region is subjected, which force is generated by the magnetic field generated by the input coil. This movement causes a variation in the capacitance measured between the two electrodes connected to the output terminals. This variation in capacitance can be detected by a suitable device, and corresponds to the desired filtering of the signal corresponding to the current injected into the input coil.

Conversely, in another scenario, the electrostatic electrodes are connected to the input terminals, and they are capable of moving one with respect to the other when a potential difference is applied to them. This movement generates a movement of the ferromagnetic region of the moveable element with respect to the metal coil.

If the moveable element is made of a hard ferromagnetic material, and forms a permanent magnet, the movement of the moveable element induces a variation in the magnetic flux inside this output coil, and therefore generates an electromotive counterforce at the terminals of the metal coil.

When the material used for the moveable element is a soft ferromagnetic material, its movement modifies the magnetic circuit of the output coil, which results in a variation of the inductance coefficient of the output coil. This variation of inductance can be detected by any suitable device.

The ferromagnetic material used on the moveable element may be either a soft ferromagnetic material or a hard ferromagnetic material; however, the latter remains preferable since it enables more force to be generated.

Various forms and architectures can be employed both for the metal coils and for the region comprising the electrodes.

Thus, the metal coil can be of the solenoid type or else of the flat spiral type; in the first case, the magnetic field generated is substantially parallel to the main plane of the substrate. The moveable element then also moves in the main plane of the substrate.

In this case, the pair of electrodes may, for example, consist of a system of interdigitated combs, also operating by moving in a direction parallel to the main plane of the substrate.

In the case where the metal coil is of the flat spiral coil type, it may for example be produced in the main plane of the substrate, and generate a magnetic field which is perpendicular to the plane of the substrate, at the centre of the coil, with field lines being contained in planes perpendicular to the main plane of the substrate, outside the coil. In this case, each of the electrodes, that is the fixed electrode and the moveable electrode, may have a configuration which is substantially parallel to the main plane of the substrate, and move one with respect to the other perpendicular to this same plane.

Various architectures can be employed with regard to the moveable element. Thus, the latter can be connected to the substrate by a single deformable portion. It may also be connected to the substrate by two or even more deformable portions located on either side of the moveable element. The shape and the size of these deformable portions are determined so that the return means have optimal stiffness, as well as enough movement amplitude and adequate solidity.

In practice, this component can be integrated into a filter with one or more poles, in combination with one or more components of the same type or of a different type.

### BRIEF DESCRIPTION OF THE FIGURES

The manner of embodying the invention and the advantages which result therefrom will emerge clearly from the description of the following two embodiments, with the support of the appended figures in which:

FIG. 1 is a rough perspective view of a component according to the invention, produced according to a first embodiment.

FIG. 2 is a top view of the component of FIG. 1.

FIG. 3 is a rough perspective view of a component according to the invention, produced according to a second embodiment.

FIG. 4 is a view in cross section, along the plane IV-IV′ of FIG. 3.

### MANNER OF EMBODYING THE INVENTION

As mentioned above, the invention relates to a microcomponent which is used in a filter with one or more poles. This microcomponent operates on the principle of converting electrical energy into kinetic energy, via phenomena of either electrostatic or magnetostatic nature, then the conversion of this kinetic energy into electrical energy via either magnetostatic or electrostatic phenomena.

The invention can be implemented by employing various architectures making it possible to obtain similar results and operating on equivalent principles.

First Embodiment of the Invention

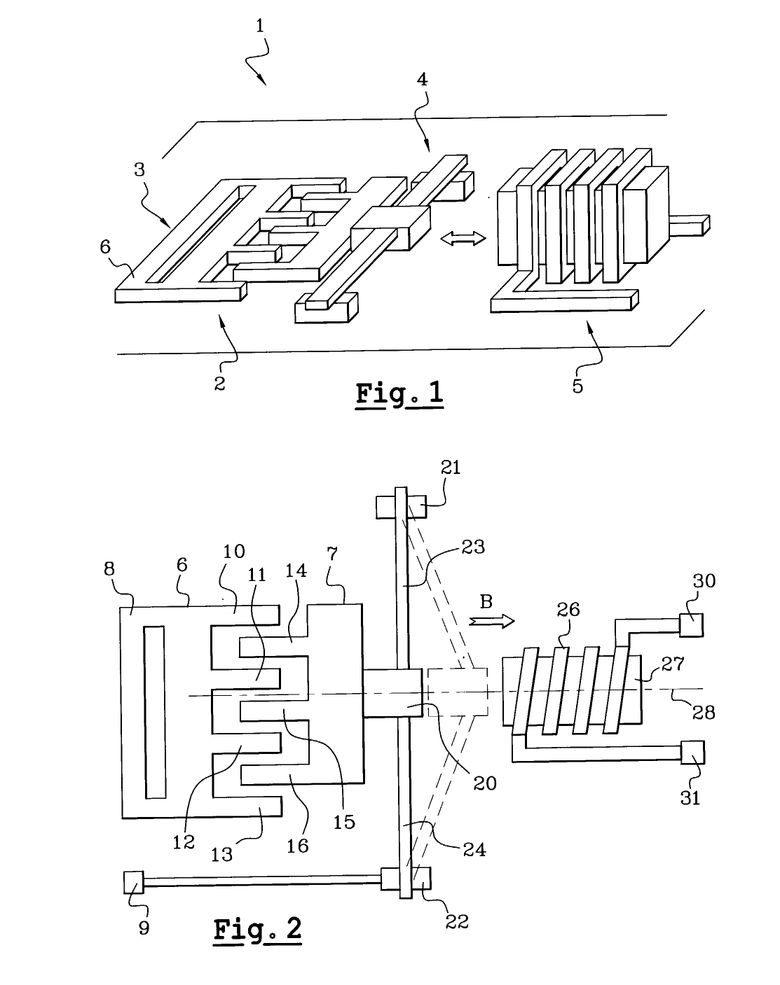

As illustrated in FIGS. 1 and 2, the microcomponent (1) can be produced on a layer of a substrate (2) based on a semiconductor, such as polysilicon.

This component (1) mainly comprises an input stage (3), a moveable element (4), and an output coil (5).

More specifically, the input stage (3) is made in the form of a pair of interdigitated combs (6, 7). One of these combs (6) is fixed with respect to the substrate (2), and is connected to one of the input terminals (8) of the filter. This comb (6) comprises a plurality of teeth (10-13) oriented towards the moveable element (4), and produced in the main plane of the substrate (2). Of course, the invention is not limited only to the form illustrated, which comprises only a limited number of teeth, for reasons of simplification, but on the contrary clearly covers all the variants operating on the same principle.

This fixed electrode (6) can be made of a metal, and according to a conventional method.

The input stage (3) also comprises a moveable plate, also formed from a comb (7) comprising a plurality of teeth (14-16). These various teeth (14-16) are interleaved between the teeth (10-13) of the fixed plate (6). The size of the various teeth, together with the depth of interpenetration are determined with respect to the desired amplitude of the movement of the moveable element (4).

The moveable plate (7) is secured to the moveable element (4), and more specifically, in the form illustrated in FIGS. 1 and 2, to a region or pad (20) made of a ferromagnetic material. This ferromagnetic pad (20) is connected to two points (21, 22), which are fixed with respect to the substrate, via two transverse flexible beams (23, 24). The length and the cross-sectional size of these beams (23, 24) are determined such that the corresponding stiffness is maximal in the direction perpendicular to the plane of the substrate, and corresponds to the value desired in the direction of movement of the pad (20) corresponding to the direction of movement of the moveable plate (7).

The moveable plate (7) is electrically connected to the second input terminal (9) via the fixed pads (21, 22) and the beams (23, 24) together with the ferromagnetic pad (20).

On the side of the moveable element (4) away from the interdigitated combs (6, 7), the microcomponent comprises a metal coil (5), made in the form of a solenoid.

This solenoid (5) comprises different metal turns (26) wound around a magnetic core (27). This solenoid (5) may, for example, be made according to the method described in document EP 1 054 417 by the Applicant. However, it may be produced according to a different method. The axis (27) of this solenoid (5) passes through the centre of the ferromagnetic pad (20), and it is aligned with the direction of movement of the moveable plate. The winding of the solenoid (5) is connected to the output terminals (30, 31) of the filter.

The device operates as follows: when a voltage is applied between the input terminals (8, 9) of the filter, electrostatic forces appear between the various teeth (10-16) of the fixed plate (6) and of the moveable plate (7). This voltage comprises an almost DC component which biases the assembly, together with an AC component, forming the signal to be filtered.

Depending on this bias voltage, on the signal to be filtered, and on the geometry of the two plates, the moveable plate (7) moves at the frequency of the signal to be filtered in the input voltage. This movement is illustrated schematically in FIG. 2, which shows, in dotted lines, the moveable element (7) in a position away from the rest position.

When the material chosen to make the ferromagnetic pad (20) is a hard ferromagnetic material, that is to say one having permanent magnetization, it generates a magnetic field which is oriented along the axis (28) of the solenoid (5). The movement of the pad (20) induces a variation in the flux of this magnetic field B inside the solenoid (5). This flux variation results in the appearance of an electromotive counter force against the two output terminals (30, 31) of the filter.

When the material used to form the ferromagnetic pad (20) is a soft ferromagnetic material, its movement parallel to the axis (28) of the solenoid (5) modifies the configuration of the magnetic circuit thereof. This variation results in a modification of the inductance coefficient of the solenoid (5). This variation can be analysed by a suitable device, or else induce a modification in a circuit into which this solenoid is integrated.

The component described above may also operate in a different way, so as to filter a signal injected into the solenoid (5). In this case, when a current passes through the solenoid (5), the magnetic field generated by the latter attracts or repels the ferromagnetic pad (20) of the moveable element (4). It follows that the moveable plate (7) moves with respect to the fixed plate (6), and therefore that the capacitance measured between the fixed plate (6) and the moveable plate (7) varies. This variation, which forms an electrical signal, can be analysed by a suitable device or be used in a circuit into which this capacitance is integrated.

Second Embodiment of the Invention

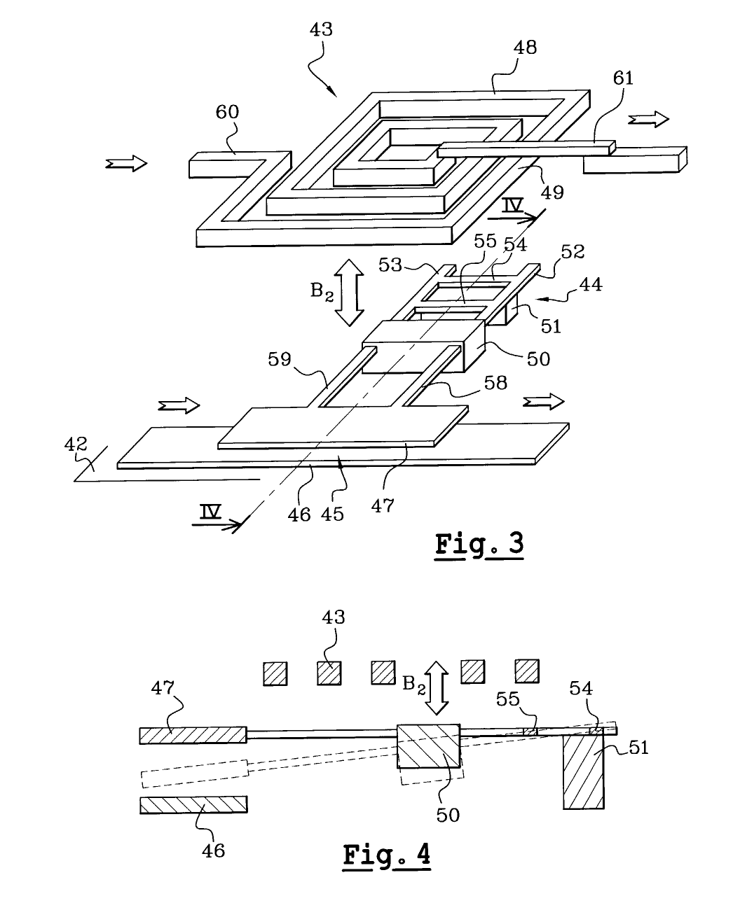

FIGS. 3 and 4 illustrate another embodiment of the invention which operates on principles similar to the first example described above, but which adopts a different geometry.

More specifically, this component (40) comprises a metal input coil (43), a moveable element (44) and a pair of plates (46, 47) forming a variable capacitance, corresponding to the output stage (45).

The input coil (43) is made in the form of a flat spiral winding, parallel to the main plane (42) of the substrate. This winding (43) has several parallel and perpendicular segments (48, 49), which can be produced in particular according to the teachings of document EP 1 039 544 of the Applicant. Nevertheless, other methods can be used to produce such windings.

When an electric current passes through the input coil (43), a magnetic field B₂ is generated, perpendicular to the plane of the winding (43), in the central region thereof.

Directly below the centre of the winding (43), there is a ferromagnetic pad (50) which is connected to a point (51), which is fixed with respect to the substrate, via two parallel beams (52, 53), themselves connected by means of two spacers (54, 55). These parallel beams (52, 53) and the spacers (54, 55) are dimensioned such that the stiffness measured in the directions included within the main plane (42) of the substrate is extremely great. On the other hand, the stiffness measured perpendicular to the main plane (42) of the substrate is adjusted to a suitable value. The presence of the spacers (54, 55) connecting the two beams (52, 53) considerably increases the torsional stiffness in the direction of the beams (52, 53).

On the opposite side, the ferromagnetic pad (50) also comprises two beams (58, 59) connecting it to a flat metal plate (47). This metal plate (47) forms the moveable plate of a variable capacitor whose fixed plate consists of a portion of a flat track (46) integrated into the substrate (42).

The device operates as follows: when a current passes through the metal coil (43), a magnetic field illustrated by the arrow B₂ is generated. This magnetic field is oriented perpendicular to the plane of the winding (43) and therefore of the substrate. The amplitude of this magnetic field varies according to the intensity of the current giving rise thereto. The magnetic field exerts a force oriented perpendicular to the substrate (42) on the ferromagnetic pad (50), which force causes the deformation of the beams (52, 53) connecting the pad (50) to the fixed point (51).

This oscillation is transmitted to the moveable plate (47) of the capacitor via the beams (58, 59). Since the distance between the moveable plate (47) and the fixed plate (46) varies, it follows that the capacitance measured between these two plates also varies. This capacitance can be measured by a suitable device via the beams (52, 53, 58, 59) and the pad (50), or else play a role in a circuit in which the capacitor is included.

The device described in FIG. 3 can be reversible, since it can operate using the capacitor formed by the plates (46, 47) as an input stage, and the flat coil (43) as an output stage. More specifically, when an AC voltage, possibly combined with a bias voltage, is applied between the fixed plate (46) and the moveable plate (47), an electrostatic force moves the moveable plate (47) towards or away from the fixed plate (46). It follows that, by virtue of the flexibility of the beams (52, 53), the ferromagnetic pad (50) moves in a direction substantially perpendicular to the plane of the substrate (42).

If the pad (50) is made of a hard ferromagnetic material, an electromotive counter force is generated between the terminals (60, 61) of the metal winding (43), as a result of the variation in flux of the magnetic field generated by the pad (50).

If the pad (50) is made of a soft magnetic material, its movement causes a modification of the magnetic circuit of the flat winding (43), and therefore a variation in the inductance coefficient thereof. It is this variation in inductance which can be used moreover, either by a device provided for this purpose, or inside a circuit including this coil, in order to form, for example, a multipole filter.

It emerges from the foregoing that the components according to the invention have many advantages, and especially that of preserving a good amplitude of movement of the moveable element, even at the high frequencies of the range employed, which makes it possible to obtain an output signal with enough amplitude for satisfactory exploitation.

1. Microelectromechanical component (1) providing filtering functions, produced on a semiconductor-based substrate, and comprising two input terminals (8, 9) and two output terminals (30, 31), characterized in that it also comprises:
a moveable element (4) connected to the substrate by at least one deformable portion (23, 24), and including a region (20) made of a ferromagnetic material;
a metal coil (5) connected to the input terminals or output terminals (30, 31), capable of interacting magnetically with the ferromagnetic region (20) of the moveable element (4);
a surface forming a first electrode (6), connected to one of the output terminals or input terminals (8), placed opposite a complementary surface (7) secured to the moveable element (4), this complementary surface (7) forming a second electrode connected to the other (9) of the output or input terminals, and being capable of interacting electrostatically with the first electrode (6).

2. Component according to claim 1, characterized in that the metal coil (5) is of the solenoid type.

3. Component according to claim 1, characterized in that the metal coil (43) is of the flat spiral coil type.

4. Component according to claim 1, characterized in that the moveable element (44) is connected to the substrate by a single deformable portion (52, 53).

5. Component according to claim 1, characterized in that the moveable element (4) is connected to the substrate by two deformable portions (23, 24) located on either side of the moveable element.

6. Component according to claim 1, characterized in that the metal coil (43) is connected to the input terminals (60, 61) and is capable of generating a magnetic field B₂ when a current flows through it, and in that the moveable element (44) is capable of moving under the effect of the force to which the ferromagnetic region (50) is subjected, which force is generated by the magnetic field generated by the metal coil (43), this movement generating a variation in the capacitance measured between the two electrodes (46, 47) connected to the output terminals.

7. Component according to claim 1, characterized in that the electrodes (6, 7) are connected to the input terminals (8, 9), and are capable of moving one with respect to the other when a potential difference is applied to them, this movement generating a movement of the ferromagnetic region (20) of the moveable element with respect to the metal coil (5).

8. Component according to claim 1, characterized in that the moveable element comprises a region made of a soft ferromagnetic material.

9. Component according to claim 1, characterized in that the moveable element comprises a region made of a hard ferromagnetic material, forming a permanent magnet.
